(19) United States
(12) Patent Application Publication
(10) Pub. No.: US 2026/0212323 A1
(43) Pub. Date: Jul. 23, 2026

(54) SMART CONSUMER GOODS COMPONENT MANUFACTURING COLLABORATION PLATFORM

(71) Applicant: INDUSWELL CORPORATION, Seoul (KR)

(72) Inventors: Moon Sook LEE, Seoul (KR); Sang Ki LEE, Yongin-si, Gyeonggi-do (KR)

(21) Appl. No.: 18/879,810

(22) PCT Filed: Dec. 27, 2022
(86) PCT No.: PCT/KR2022/021416

§ 371 Date: Sep. 10, 2025

(30) Foreign Application Priority Data
Dec. 27, 2022 (KR) 10-2022-0185762

(51) Int. Cl. G06Q 10/101

(52) U.S. Cl. CPC G06Q 10/101

(57) ABSTRACT

The present invention relates to a smart consumer goods component manufacturing collaboration platform which, by converging the fields of manufacturing and soft power, enables all processes of the manufacturing industry to be carried out in an intelligent manner and be interconnected, thereby expanding the manufacturing industry value chain and promoting the realization of high added value of small and medium-sized manufacturing enterprises. The smart consumer goods component manufacturing collaboration platform is provided with: an artificial intelligence-based smart manufacturing collaboration platform which enables the implementation of a manufacturing industry business service, and uses edge computing technology to process manufacturing collaboration data collected through a data channel for collecting manufacturing collaboration data through user terminals and multiple channels, models the manufacturing collaboration data using an artificial intelligence-based model, and carries out a virtual simulation, thereby generating optimized manufacturing collaboration data; and an artificial intelligence-based real-time demand forecasting and big data analysis service which processes raw manufacturing collaboration data by using edge computing technology, and generates demand forecast information by analyzing the processed manufacturing collaboration data by using an artificial intelligence visualization and analysis tool.

### TECHNICAL FIELD

The present invention relates to a smart consumer goods component manufacturing collaboration platform, and more specifically, to a smart consumer goods component manufacturing collaboration platform, which expands a manufacturing industry value chain and promotes realization of a high added value in small and medium-sized manufacturing industries by intellectualizing and interconnecting all processes of the manufacturing industries through convergence between fields of manufacturing and soft power.

### BACKGROUND ART

The domestic manufacturing industry is limited in corporate growth as it focuses only on securing competitiveness in manufacturing costs and enhancing productivity due to the limitations of market growth.

From the perspective of small and medium-sized companies from the past to the present, the small and medium-sized companies have to invest in all processes of producing a product from product planning to design, molding, and sales, and the small and medium-sized companies also have to take the associated risks, so that the small and medium-sized companies are burdened with the development of new products, and as a result, product development becomes passive and discouraged.

In other words, the process of manufacturing a product requires a variety of workers in various fields, such as a planner who plans the product, a raw materials supplier who supplies the raw materials for the product, a designer who designs the product, a producer who manufactures the product, and a delivery person who delivers the raw materials or finished product. However, the small and medium-sized companies face various difficulties, such as economic issues, in securing all of these workers and operating the business.

In addition, the small and medium-sized companies are aware of the need for strategies to change market trends and met customer satisfaction and the need for innovation and advancement, but the reality is that there is a lack of time/human capacity to learn systematic methodology. Although efforts are made to acquire methodologies through external consulting for company growth, there is a concern that this may lead to risks through unrealistic formal consulting.

Therefore, in order to grow the small and medium-sized manufacturing industries, it is necessary to construct a multilateral collaboration environment through active participation of various stakeholders (design companies, investors, small and medium-sized manufacturers, consumers) by utilizing crowdsourcing techniques, and it is necessary to develop a manufacturing collaboration integrated platform technology capable of reducing the burden of new product development and increasing a product value using each strength.

### DETAILED DESCRIPTION OF INVENTION

### Technical Problem

Therefore, the present invention has been proposed to promote the convergence between fields of manufacturing and soft power and realize a high added value in small and medium manufacturing industries by supporting a cooperative service for manufacturing a smart consumer goods component that is insufficient in the general small and medium manufacturing industries, and an object of the present invention is to provide a smart consumer goods component manufacturing collaboration platform, which expands a manufacturing industry value chain and promotes realization of a high added value in small and medium-sized manufacturing industries by intellectualizing and interconnecting all processes of the manufacturing industries through convergence between fields of manufacturing and soft power.

Another object of the present invention is to provide a smart consumer goods component manufacturing collaboration platform, which collects, analyzes, and predicts manufacturing process information in real time and utilizes results thereof by converging activities such as planning, design, production, logistics, distribution, sales, and marketing, which are a series of processes in manufacturing industries, using high-tech information communication technologies (artificial intelligence, Internet of Things, cloud computing, big data, mobile, etc.) and high-tech technologies (robot, 3D printing, and CPS).

### Technical Solution

To achieve the objects as described above, a “smart consumer goods component manufacturing collaboration platform” according to the present invention includes:
a user terminal configured to provide component manufacturing collaboration-related information or utilize the information;
a data channel configured to collect manufacturing collaboration data through the user terminal and a plurality of channels;
an artificial intelligence-based smart manufacturing collaboration platform configured to process the manufacturing collaboration data, which is collected through the data channel, through an edge computing technology, to model the manufacturing collaboration data into an artificial intelligence-based model, to generate optimized manufacturing collaboration data through virtual simulation, and to implement a manufacturing business service;
an artificial intelligence-based real-time demand prediction and big data analysis service unit configured to collect manufacturing collaboration raw data through an Internet of Things (IoT), to process the collected manufacturing collaboration raw data through the edge computing technology, and to generate demand prediction information by analyzing the processed manufacturing collaboration data through data collection, conversion, and indexing processes using an artificial intelligence visualization and analysis tool;
an integrated database configured to store, integrate, and manage the manufacturing collaboration data that is processed by the artificial intelligence-based smart manufacturing collaboration platform and the demand prediction information that is generated by the artificial intelligence-based real-time demand prediction and big data analysis service unit; and
a company legacy system configured to implement a manufacturing collaboration service between companies by collaborating the artificial intelligence-based smart manufacturing collaboration platform and the integrated database.

In addition, the “smart consumer goods component manufacturing collaboration platform” may further include:
a task processing unit configured to monitor the data collected through the data channel, manage templates and users, and process integrated data sharing; and
a service processing unit configured to process services such as a security function, user management, and integrated management.

The task processing unit may include:
a community and custom service module configured to support services such as community between manufacturing companies, template management, user management, and menu management; and
a core service module configured to support services such as real-time monitoring, integrated data sharing, and engine linkage.

The service processing unit
may process an SSO/security service, process the user management service, and support the integrated management service.

The artificial intelligence-based smart manufacturing collaboration platform may include:
an input data processing unit configured to process the manufacturing collaboration data, which is collected through a plurality of data channels, through the edge computing technology, and to process a task;
a data transmission unit configured to generate a process event for the data processed by the input data processing unit;
an artificial intelligence event processing unit configured to process the event, which is transmitted through the data transmission unit, using the artificial intelligence-based model;
an artificial intelligence-based control unit configured to provide an artificial intelligence-based processing model such that the artificial intelligence event processing unit processes the event; and
a task processing unit configured to process the task by interworking with the artificial intelligence event processing unit.

The input data processing unit may include:
a data collection agent configured to collect manufacturing collaboration-related data through the edge computing technology;
a data refinement and conversion processing unit configured to refine the manufacturing collaboration data collected through the data collection agent, and to convert the manufacturing collaboration data into data that is utilizable in the artificial intelligence-based model;
a data storage and search engine storage unit configured to store the data processed by the data refinement and conversion processing unit, and to store a search engine; and
a data visualization dashboard configured to display the processed data through visualization.

The artificial intelligence-based smart manufacturing collaboration platform may further include:
an intelligent business service unit configured to provide a manufacturing collaboration service and an artificial intelligence-based engine; and
a common service unit configured to process common services between manufacturing companies, which include information management, user management, and log management.

The intelligent business service unit may include:
a business service module configured to support business services including task guidance, collaboration management, schedule management, contract/arbitration management, issue management, business management, and quality management; and
an artificial intelligence (AI)-based engine module configured to provide a collaborative matching engine, a big data analysis engine, an arbitration management engine, a search engine, a performance management engine, and a demand prediction engine.

The common service unit
may support common services including reference information management, common management, user management, bulletin board management, company pool management, log management, and community.

### Advantageous Effects

According to the present invention, it is possible to expand a manufacturing industry value chain and promote realization of a high added value in small and medium-sized manufacturing industries by intellectualizing and interconnecting all processes of the manufacturing industries through convergence between fields of manufacturing and soft power.

In addition, according to the present invention, it is possible to promote collection, analysis, and prediction of manufacturing process information in real time and utilization of results thereof by converging activities such as planning, design, production, logistics, distribution, sales, and marketing, which are a series of processes in manufacturing industries, using high-tech information communication technologies (artificial intelligence, Internet of Things, cloud computing, big data, mobile, etc.) and high-tech technologies (robot, 3D printing, and CPS).

In addition, according to the present invention, it is possible to promote a reduction in burden of new product development and an increase in a product value using each strength, by constructing a multilateral collaboration environment through active participation of various stakeholders (design companies, investors, small and medium-sized manufacturers, and consumers) using crowdsourcing techniques, in order to grow the small and medium-sized manufacturing industries.

### DESCRIPTION OF DRAWINGS

FIG. 1 is a configuration diagram of a smart consumer goods component manufacturing collaboration platform according to the present invention.

FIG. 2 is a structural diagram of a manufacturing collaboration platform storage applied to the present invention.

FIG. 3 is a functional structural diagram of the manufacturing collaboration platform applied to the present invention.

FIG. 4 is a configuration diagram of an example of an input data processing unit of FIG. 1.

### BEST MODE FOR INVENTION

Hereinafter, a smart consumption goods component manufacturing collaboration platform according to preferred embodiments of the present invention will be described in detail with reference to the accompanying drawings.

The terms or words used throughout the present invention, which will be described below, should not be limitedly interpreted based on the typical meaning or the meaning of the dictionary but should be interpreted as the meaning and concept which may well match with the technical concept of the present invention based on the principle where the inventor himself/herself may properly define the concepts of the terms so as to describe his/her invention in the best way.

Accordingly, the embodiments described in the present specification and the configurations shown in the drawings are merely preferred embodiments according to the present disclosure, and do not represent all of the technical ideas of the present invention. Therefore, it should be understood that various equivalents and modifications may be substituted therefor at the time of filing of the present application.

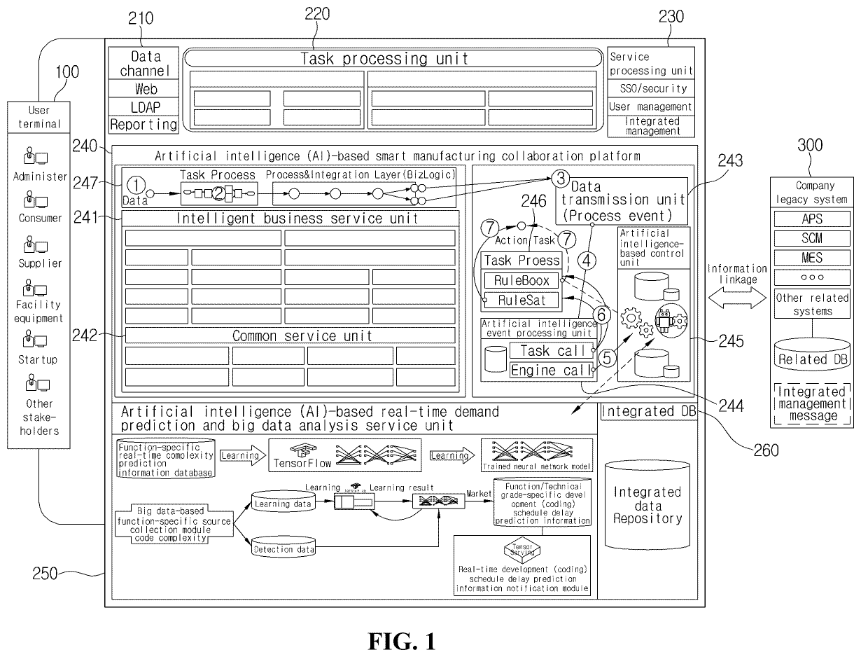

FIG. 1 is a configuration diagram of a smart consumer goods component manufacturing collaboration platform according to preferred embodiments of the present invention, in which the smart consumer goods component manufacturing collaboration platform may include a user terminal configured to provide component manufacturing collaboration-related information or utilize the information.

In this case, the user terminal 100 may include a manager terminal used by a manager who manages manufacturing collaboration-related information, a consumer terminal used by a consumer who needs manufacturing collaboration data and demand prediction information, a supplier terminal used by a supplier who provides manufacturing collaboration data and demand prediction data, a facility equipment terminal used by a user who provides manufacturing collaboration-related equipment information, a startup terminal used by a manufacturing startup-related person, and other terminals used by manufacturing-related stakeholders.

In addition, the smart consumer goods component manufacturing collaboration platform according to the present invention may include a data channel 210 that collects manufacturing collaboration data through the user terminal 100 and a plurality of channels (Web, LDAP, and Reporting), a task processing unit 220 that monitors the data collected through the data channel 210, manages templates and users, and processes integrated data sharing, and a service processing unit 230 that processes services such as a security function, user management, and integrated management.

The task processing unit 220 may include a community and custom service module that supports services such as community between manufacturing companies, template management, user management, and menu management, and a core service module that supports services such as real-time monitoring, integrated data sharing, and engine linkage.

In addition, the service processing unit 230 may process an SSO/security service, process a user management service, and support an integrated management service.

In addition, the smart consumer goods component manufacturing collaboration platform according to the present invention may include an artificial intelligence-based smart manufacturing collaboration platform 240 that processes the manufacturing collaboration data, which is collected through the data channel, through an edge computing technology, models the manufacturing collaboration data into an artificial intelligence-based model, generates optimized manufacturing collaboration data through virtual simulation, and implements a manufacturing business service.

The artificial intelligence-based smart manufacturing collaboration platform 240 controls/manages various production processes to allow interworking with an upper-level application.

The artificial intelligence-based smart manufacturing collaboration platform 240 may include an input data processing unit 247 that processes the manufacturing collaboration data, which is collected through a plurality of data channels, through the edge computing technology, and processes a task, a data transmission unit 243 that generates a process event for the data processed by the input data processing unit 247, an artificial intelligence event processing unit 244 that processes the event, which is transmitted through the data transmission unit 243, using the artificial intelligence-based model, an artificial intelligence-based control unit 245 that provides an artificial intelligence-based processing model such that the artificial intelligence event processing unit 244 processes the event, and a task processing unit 246 that processes the task by interworking with the artificial intelligence event processing unit 244.

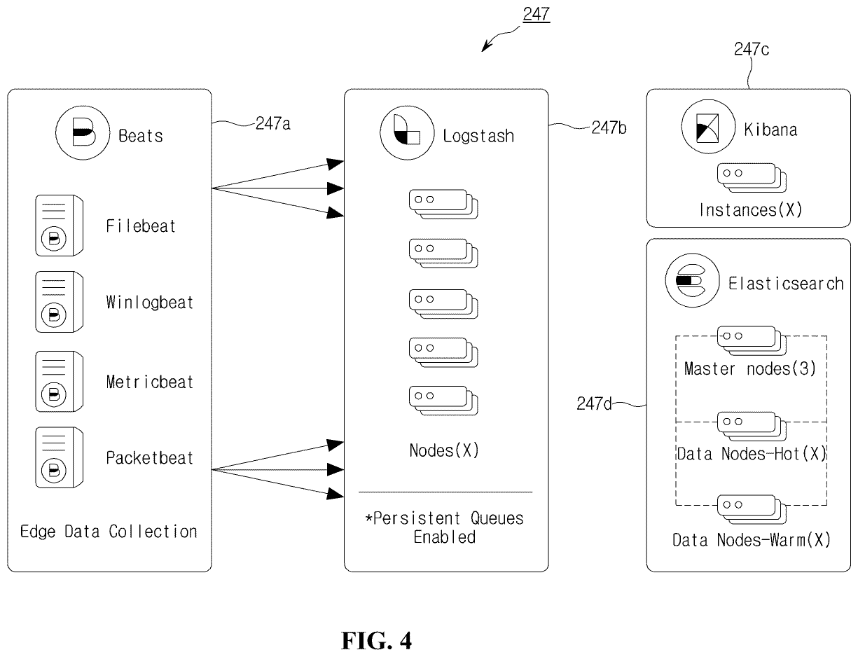

As shown in FIG. 4, the input data processing unit 247 may include a data collection agent 247a that collects manufacturing collaboration-related data through the edge computing technology, a data refinement and conversion processing unit 247b that refines the manufacturing collaboration data collected through the data collection agent 247a, and converts the manufacturing collaboration data into data that is utilizable in the artificial intelligence-based model, a data storage and search engine storage unit 247d that stores the data processed by the data refinement and conversion processing unit 247b, and stores a search engine, a data visualization dashboard 247c that displays the processed data through visualization.

In addition, the artificial intelligence-based smart manufacturing collaboration platform 240 may include an intelligent business service unit 241 that provides a manufacturing collaboration service and an artificial intelligence-based engine, and a common service unit 242 that processes common services between manufacturing companies, which include information management, user management, and log management.

The intelligent business service unit 241 may include a business service module that supports business services including task guidance, collaboration management, schedule management, contract/arbitration management, issue management, business management, and quality management, and an artificial intelligence (AI)-based engine module that provides a collaborative matching engine, a big data analysis engine, an arbitration management engine, a search engine, a performance management engine, and a demand prediction engine.

The common service unit 242 may support common services including reference information management, common management, user management, bulletin board management, company pool management, log management, and community.

In addition, the smart consumer goods component manufacturing collaboration platform according to the present invention may include an artificial intelligence-based real-time demand prediction and big data analysis service unit 250 that collects manufacturing collaboration raw data through the Internet of Things (IoT), processes the collected manufacturing collaboration raw data through the edge computing technology, and generates demand prediction information by analyzing the processed manufacturing collaboration data through data collection, conversion, and indexing processes using an artificial intelligence visualization and analysis tool, an integrated database 260 that stores, integrates, and manages the manufacturing collaboration data that is processed by the artificial intelligence-based smart manufacturing collaboration platform 240 and the demand prediction information that is generated by the artificial intelligence-based real-time demand prediction and big data analysis service unit 250, and a company legacy system 300 that implements a manufacturing collaboration service between companies by collaborating the artificial intelligence-based smart manufacturing collaboration platform 240 and the integrated database 260.

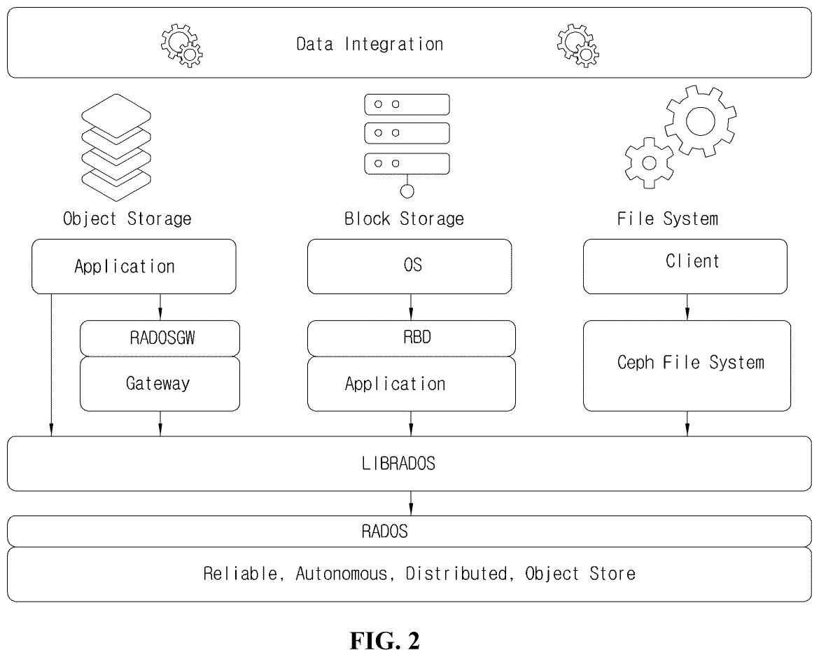

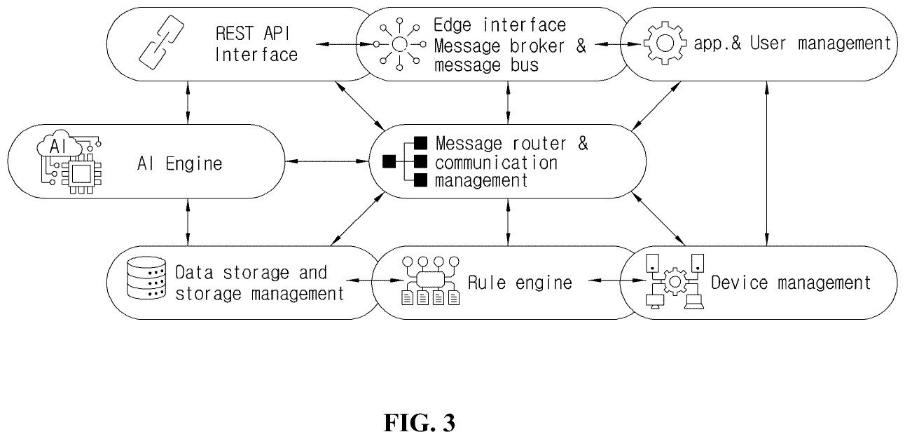

An operation of the smart consumer goods component manufacturing collaboration platform according to the preferred embodiment of the present invention configured as described above will be described in detail with reference to a structural diagram of a manufacturing collaboration platform storage of FIG. 2 and a functional structure of the manufacturing collaboration platform of FIG. 3 as follows.

First, manufacturing-related personnel access the manufacturing collaboration platform through a network using the user terminal 100, and provide smart consumer goods component manufacturing collaboration-related information or implement a factory-free manufacturing industry using the provided information.

In this case, as well known, the user terminal 100 may include a manager terminal, a recipient terminal, a supplier terminal, a facility equipment terminal, a startup terminal, and an interested party terminal.

The user terminal 100 may be implemented as a mobile device such as a smartphone, a personal computer (PC), or a server.

The data channel 210 collects manufacturing collaboration data through the user terminal 100 and a plurality of channels (Web, LDAP, and Reporting) and transmits the collected manufacturing collaboration data to the artificial intelligence-based smart manufacturing collaboration platform 240.

In this case, the task processing unit 220 monitors the data collected through the data channel 210, manages templates and users, and process integrated data sharing.

To this end, the task processing unit 220 may include a community and custom service module that supports services such as community between manufacturing companies, template management, user management, and menu management, and a core service module that supports services such as real-time monitoring, integrated data sharing, and engine linkage.

In addition, the service processing unit 230 processes services such as a security function, user management, and integrated management when utilizing the smart consumer goods component manufacturing collaboration platform.

Meanwhile, the artificial intelligence-based smart manufacturing collaboration platform 240 processes the manufacturing collaboration data, which is collected through the data channel 210, through an edge computing technology, models the manufacturing collaboration data into an artificial intelligence-based model, generates optimized manufacturing collaboration data through virtual simulation, and implements a manufacturing business service.

The artificial intelligence-based smart manufacturing collaboration platform 240 provides an execution platform for manufacturing collaboration of smart consumer goods components in stages such as product planning, development, production, and packaging.

In particular, the artificial intelligence-based smart manufacturing collaboration platform 240 provides a manufacturing collaboration platform for consumer goods components to activate a collaboration ecosystem between service companies and product production companies in various manufacturing domains.

In general, it is difficult for manufacturing companies to interwork between factories, so that the manufacturing companies produce only fixed products through fixed processes in a single factory, and it is difficult to release new products due to difficulties in technology convergence to realize smart consumer goods. The artificial intelligence-based smart manufacturing collaboration platform provides information such as human resources and materials through a collaboration platform between manufacturing companies, an open service platform, a manufacturing ecosystem configuration, and a cloud-based hyper-connected cooperative operation service, and promotes optimization of the artificial intelligence-based production process. Therefore, it is possible to promote checking of geographically dispersed factories by manufacturing stage, efficient product production through collaboration between specialized factories, and production of various smart products through a collaboration.

Through the provision of the manufacturing collaboration platform, it is possible to expand a manufacturing industry value chain and realize a high added value in small and medium-sized manufacturing industries by intellectualizing and interconnecting all processes of the manufacturing industries through convergence between fields of manufacturing and soft power.

The value chain used herein means that a value is transmitted to a customer through all processes of project registration, monitoring, material component procurement order management, material management, production management, shipment, delivery, and high-color services, and an accumulated value in each process forms the profits of a company.

For example, the input data processing unit 247 of the artificial intelligence-based smart manufacturing collaboration platform 240 processes the manufacturing collaboration data, which is collected through a plurality of data channels 210, through edge computing technology, and processes a task.

That is, as shown in FIG. 4, the input data processing unit 247 collects the manufacturing collaboration-related data through the edge computing technology in the data collection agent 247a. The edge computing enables on-site management and control through on-site facility monitoring.

The data refinement and conversion processing unit 247b refines the manufacturing collaboration data collected through the data collection agent 247a, converts the refined manufacturing collaboration data into data that is utilizable in the artificial intelligence-based model, and provides the collected manufacturing collaboration data.

In addition, the data storage and search engine storage unit 247d serves to store the data processed by the data refinement and conversion processing unit 247b. In this case, the data storage and search engine storage unit 247b also serves to store a search engine.

The data visualization dashboard 247c logically visualizes and displays physical resources based on the processed data.

In addition, the data transmission unit 243 generates a process event for the data processed by the input data processing unit 247, and the artificial intelligence event processing unit 244 processes an event for the process event using the artificial intelligence-based model.

In this case, as the artificial intelligence-based model for event processing, the AI-based model may be derived and used by ensemble learning that learns several models using a decision tree algorithm, a naive bayes classification algorithm, a K-nearest neighbor (KNN) algorithm, a support vector machine, and the like.

In this case, the artificial intelligence-based control unit 245 provides an artificial intelligence-based processing model to process an event in the artificial intelligence event processing unit 244, and performs overall control for event processing.

When the artificial intelligence event processing unit 244 processes an event, the task processing unit 246 processes tasks such as RuleSet and RuleBook by interworking with the artificial intelligence event processing unit 244.

In addition, the artificial intelligence-based smart manufacturing collaboration platform 240 supports an intelligent business service and a common service through the intelligent business service unit 241 that provides a manufacturing collaboration service and an artificial intelligence-based engine, and the common service unit 242 that processes common services between manufacturing companies, which include information management, user management, and log management.

The intelligent business service unit 241 supports business services for task guidance, collaboration management, schedule management, contract/arbitration management, issue management, business management, and quality management through the business service module.

In this case, collaboration management allows consumers and suppliers to share the progress of collaboration, stores decision-making processes and related data as records, and performs reliability verification of companies during collaboration.

In addition, a collaborative matching engine, a big data analysis engine, an arbitration management engine, a search engine, a performance management engine, and a demand prediction engine are provided through the artificial intelligence-based engine module.

The search engine serves to recommend search results selected by a user who has the same keyword of interest among other users who input the same search word, and to provide information in the order of recording the largest number of views.

In addition, the collaborative matching engine serves to analyze a company according to basic information and activities of a recipient and a supplier, and select a collaboration target through recommendation and matching of a manufacturer and consultation with the proposal companies through the community so as to match a manufacturing company.

The common service unit 242 may support common services including reference information management, common management, user management, bulletin board management, company pool management, log management, and community.

In this case, the company pool management serves to provide and manage general information of manufacturing companies such as fields, production items, and addresses, to provide information such as portfolio and keywords, and to provide information such as the latest news related to the company.

In addition, the artificial intelligence-based real-time demand prediction and big data analysis service unit 250 of the smart consumer goods component manufacturing collaboration platform according to the present invention collects manufacturing collaboration raw data through an Internet of Things (IoT), processes the collected manufacturing collaboration raw data through an edge computing technology, and generates demand prediction information through analysis of the processed manufacturing collaboration data through data collection, conversion, and indexing processes by using an artificial intelligence visualization and analysis tool.

The generated demand prediction information and the manufacturing collaboration data processed by the artificial intelligence-based smart manufacturing collaboration platform 240 are registered and managed in the integrated database 260

The company legacy system 300 implements a manufacturing collaboration service between companies by collaborating the artificial intelligence-based smart manufacturing collaboration platform 240 and the integrated database 260.

According to the present invention described above, it is possible to expand a manufacturing industry value chain and promote realization of a high added value in small and medium-sized manufacturing industries by intellectualizing and interconnecting all processes of the manufacturing industries through convergence between fields of manufacturing and soft power.

In addition, it is possible to promote collection, analysis, and prediction of manufacturing process information in real time and utilization of results thereof by converging activities such as planning, design, production, logistics, distribution, sales, and marketing, which are a series of processes in manufacturing industries, using high-tech information communication technologies (artificial intelligence, Internet of Things, cloud computing, big data, mobile, etc.) and high-tech technologies (robot, 3D printing, and CPS).

In addition, it is possible to promote a reduction in burden of new product development and an increase in a product value using each strength, by constructing a multilateral collaboration environment through active participation of various stakeholders (design companies, investors, small and medium-sized manufacturers, and consumers) using crowdsourcing techniques, in order to grow the small and medium-sized manufacturing industries.

Although the present invention invented by the present inventor has been described in detail with reference to the embodiments, the present invention is not limited to the above embodiments, and it is obvious to those skilled in the art that various modifications are possible without departing from the gist of the present invention.

### INDUSTRIAL APPLICABILITY

The present invention may be applied to a technology for component manufacturing collaboration of smart consumer goods in small and medium-sized manufacturing industries.

1. A smart consumer goods component manufacturing collaboration platform comprising:
a user terminal configured to provide component manufacturing collaboration-related information or utilize the information;
a data channel configured to collect manufacturing collaboration data through the user terminal and a plurality of channels;
an artificial intelligence-based smart manufacturing collaboration platform configured to process the manufacturing collaboration data, which is collected through the data channel, through an edge computing technology, to model the manufacturing collaboration data into an artificial intelligence-based model, to generate optimized manufacturing collaboration data through virtual simulation, and to implement a manufacturing business service;
an artificial intelligence-based real-time demand prediction and big data analysis service unit configured to collect manufacturing collaboration raw data through an Internet of Things (IoT), to process the collected manufacturing collaboration raw data through the edge computing technology, and to generate demand prediction information by analyzing the processed manufacturing collaboration data through data collection, conversion, and indexing processes using an artificial intelligence visualization and analysis tool;
an integrated database configured to store, integrate, and manage the manufacturing collaboration data that is processed by the artificial intelligence-based smart manufacturing collaboration platform and the demand prediction information that is generated by the artificial intelligence-based real-time demand prediction and big data analysis service unit; and
a company legacy system configured to implement a manufacturing collaboration service between companies by collaborating the artificial intelligence-based smart manufacturing collaboration platform and the integrated database.

2. The smart consumer goods component manufacturing collaboration platform of claim 1, further comprising:
a task processing unit configured to monitor the data collected through the data channel, manage templates and users, and process integrated data sharing; and
a service processing unit configured to process services such as a security function, user management, and integrated management.

3. The smart consumer goods component manufacturing collaboration platform of claim 2, wherein the task processing unit includes:
a community and custom service module configured to support services such as community between manufacturing companies, template management, user management, and menu management; and
a core service module configured to support services such as real-time monitoring, integrated data sharing, and engine linkage.

4. The smart consumer goods component manufacturing collaboration platform of claim 2, wherein the service processing unit processes an SSO/security service, processes the user management service, and supports the integrated management service.

5. The smart consumer goods component manufacturing collaboration platform of claim 1, wherein the artificial intelligence-based smart manufacturing collaboration platform includes:
an input data processing unit configured to process the manufacturing collaboration data, which is collected through a plurality of data channels, through the edge computing technology, and to process a task;
a data transmission unit configured to generate a process event for the data processed by the input data processing unit;
an artificial intelligence event processing unit configured to process the event, which is transmitted through the data transmission unit, using the artificial intelligence-based model;
an artificial intelligence-based control unit configured to provide an artificial intelligence-based processing model such that the artificial intelligence event processing unit processes the event; and
a task processing unit configured to process the task by interworking with the artificial intelligence event processing unit.

6. The smart consumer goods component manufacturing collaboration platform of claim 5, wherein the input data processing unit includes:
a data collection agent configured to collect manufacturing collaboration-related data through the edge computing technology;
a data refinement and conversion processing unit configured to refine the manufacturing collaboration data collected through the data collection agent, and to convert the manufacturing collaboration data into data that is utilizable in the artificial intelligence-based model;
a data storage and search engine storage unit configured to store the data processed by the data refinement and conversion processing unit, and to store a search engine; and
a data visualization dashboard configured to display the processed data through visualization.

7. The smart consumer goods component manufacturing collaboration platform of claim 1, wherein the artificial intelligence-based smart manufacturing collaboration platform includes:
an intelligent business service unit configured to provide a manufacturing collaboration service and an artificial intelligence-based engine; and
a common service unit configured to process common services between manufacturing companies, which include information management, user management, and log management.

8. The smart consumer goods component manufacturing collaboration platform of claim 7, wherein the intelligent business service unit includes:
a business service module configured to support business services including task guidance, collaboration management, schedule management, contract/arbitration management, issue management, business management, and quality management; and
an artificial intelligence (AI)-based engine module configured to provide a collaborative matching engine, a big data analysis engine, an arbitration management engine, a search engine, a performance management engine, and a demand prediction engine.

9. The smart consumer goods component manufacturing collaboration platform of claim 7, wherein the common service unit supports common services including reference information management, common management, user management, bulletin board management, company pool management, log management, and community.
